(19) United States
(12) Patent Application Publication
(10) Pub. No.: US 2004/0159884 A1
(43) Pub. Date: Aug. 19, 2004

(54) Semiconductor device and a method for manufacturing the same

(76) Inventor: Fumitomo Matsuoka, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/779,661

(22) Filed: Feb. 18, 2004

Related U.S. Application Data
(62) Division of application No. 09/816,393, filed on Mar. 26, 2001.

(30) Foreign Application Priority Data
Mar. 31, 2000 (JP) 2000-096442

(51) Int. Cl. H01L 33/00

(52) U.S. Cl. 257/327

(57) ABSTRACT

A MISFET having a buried gate is formed by forming a dummy gate electrode on a semiconductor substrate, forming source/drain regions with the dummy electrode as a mask, after forming an insulating film in a way to bury the dummy gate electrode, while exposing an upper surface of the dummy gate, removing the dummy gate electrode and forming a first trench in the insulating film, enlarging the width of the first trench to provide a second trench in the insulating film which is wider than the first trench, forming a gate insulating film along the inner surface of the second trench, and forming a gate electrode in the second trench with the gate insulating film intervening therebetween. By doing so it is possible to control an offset between the end of the gate electrode and the ends of source/drain diffusion layers and a MISFET thus obtained operates stably.

### CROSS-REFERENCE TO RELATED APPLICATIONS

This application is based upon and claims the benefit of priority from the prior Japanese Patent Application No. 2000-096442, filed Mar. 31, 2000, the entire contents of which are incorporated herein by reference.

### BACKGROUND OF THE INVENTION

1. Field of the Invention

The present invention relates to an insulated gate field effect transistor (hereinafter referred to as a MISFET) using a buried-type gate electrode structure and a method for manufacturing the same.

2. Description of the Related Art

A conventional manufacturing process for manufacturing a MISFET using a buried type gate electrode structure will be explained below with reference to FIGS. 1 to 8. After an isolation region 102 is formed on a P type semiconductor substrate 101, for example, an about 5 nm-thick Si oxide film 103 is deposited by a thermal oxidation method on a resultant surface, the Si oxide film 103 serving as a dummy gate insulating film. Thereafter, an about 100 nm-thick polycrystalline silicon film serving as a dummy gate electrode is deposited on a surface with the use of a chemical vapor deposition method, followed by the formation of an about 50 nm-thick silicon nitride film 105 by the same chemical vapor deposition method.

Then a resist 106 is formed on a whole surface and it is etched by a photolithography method to a predetermined pattern. With the patterned resist 106 as a mask, a stack layer structure of the polycrystalline silicon film 104 and silicon nitride film 105 is etched by an anisotropic etching to a predetermined configuration. By doing so, a dummy gate electrode 115 is formed. After the removal of the resist 106, regions 107 later providing extension regions of source/drain impurity diffusion layers are formed, in a self-aligned way, by an ion implantation method with the dummy gate electrode used as a mask (FIG. 1).

Then an about 100 nm-thick silicon nitride film is deposited by the chemical vapor deposition method, etc., and a resultant surface is anitsotropically etched to leave the silicon nitride film only on a sidewall portion of the dummy gate electrode 115 and a sidewall insulating film 108 is formed. Thereafter, with the sidewall silicon nitride film 108 and dummy gate electrode 115 used as a mask, an ion implantation step is carried out to provide impurity diffusion regions (source/drain) 109 having a deep junction (FIG. 2).

After an about 20 nm-thick Co film, etc. has been deposited on a whole surface, followed by a thermal treatment. By doing so, a Co silicide film 110 is formed only at those areas where the Co film and Si film are contacted with each other. Thus a salicide (self-aligned silicide) structure is provided (FIG. 3).

Thereafter, an about 400 nm-thick insulating film, such as an SiO₂ film, serving as an interlayer insulator 111 is deposited by the chemical vapor deposition method on a whole surface. This insulator. has its whole surface polished by a CMP (Chemical Mechanical Polishing) method to a height level of the dummy gate electrode 115 comprised of a stacked layer structure of the polycrystalline silicon film 104 and silicon nitride film 105 to be the interlayer insulator 111.

Thereafter, the silicon nitride film 105 of the dummy gate electrode 115 is removed by an etching having a selectivity between the silicon oxide film and the silicon nitride film and the polycrystalline silicon film 104 of the dummy gate electrode 115 is removed by an etching having a selectivity between the silicon oxide film and polycrystalline silicon film. By doing so, a trench 112 for burying a final gate electrode material therein is formed (FIG. 4).

Thereafter, a silicon oxide film is formed, by a thermal oxidation method, as a 3 nm-thick gate insulating film 113 (FIG. 5). Further, an about 300 nm-thick tungsten is deposited, by the chemical vapor deposition method, as a final gate electrode material on a whole surface and a planarization step is done by the CMP method to complete a buried-type gate electrode 114 (FIG. 6).

In the MISFET using a buried type gate electrode structure formed by such a method, the degree of freedom with which the gate insulating film and gate electrode material are selected is increased. However, the following problem arises.

In recent years, due to the microminiaturization of such elements, the gate length of the MISFET has been made very fine and the gate insulating film has been made vary thin. For example, in the adoption of a silicon oxide film thinner than 2 nm (physical film thickness) as a gate insulating film, difficulty is encountered due to its tunnel current, etc., as well as the reliability problem involved. For this reason, in place of such silicon oxide film, the adoption of a high dielectric-constant film, such as a silicon nitride film and Ta₂O₅ film, has been studied because it can be increased in thickness.

In an example of FIG. 7, after the dummy gate electrode 115 has been removed as shown in FIG. 5 to provide a trench for a final buried type gate electrode formation, a high dielectric-constant film, such as the Ta₂O₅, is formed, as a gate insulating film 201, by using the chemical vapor deposition method, etc., in place of forming the above-mentioned silicon oxide film by the thermal oxidation method. The above-mentioned high dielectric-constant film, being formed by the chemical vapor deposition method and sputtering method, is formed, as shown in FIG. 7, also on the sidewall of the trench for the gate electrode formation.

Since, on the other hand, the high dielectric-constant film is higher in dielectric constant than the silicon oxide film, it is required that, in order to obtain a capacitance equivalent to the SiO₂ film of, for example, 2 nm, the film thickness be increased to about 40 to 60 nm. In this connection it is to be noted that the relative dielectric constant-of the SiO₂ is 3.9; that of an Si₃N₄ is about 7; that of Al₂O₃ (alumna) is about 10; and that of Ta₂O₅ is about 25.

FIG. 8 is a cross-sectional view of a MISFET after a gate electrode has been buried in which case such high dielectric-constant film is used as the gate insulating film. At this time, an area now under consideration is an area 203, as enclosed in FIG. 8, between the ends of the gate 202 and source/drain diffusion layers.

In the MISFET, as shown in FIG. 6, usually, the end of the gate electrode 114 is aligned, at least in a horizontal position relation, with these ends of the source/drain diffusion layers with the gate insulating film 113 intervening therebetween or the ends of the source/drain diffusion layers 109 partially overlap the gate electrode 114 in such a relation. This is required to operate a MISFET.

In the prior art technique, as set out above, the gate insulating film 201 as thick as 40 to 60 nm has to be formed, as indicated in FIG. 8, on the bottom surface-and sidewall surface of the gate electrode burying trench 212. For this reason, the ends of the source/drain diffusion layers and end of the gate electrode 202 are spaced apart from each other by a distance X (indicated by 203 in FIG. 8) corresponding to the film thickness of the gate insulating film 201 formed on the inner sidwall of the gate electrode burying trench 212. This provides what is called an offset structured MISFET, thus causing some inconvenience from the standpoint of the operation of the element. Such inconvenience becomes prominent as the width of the gate electrode burying trench becomes smaller and smaller.

### BRIEF SUMMARY OF THE INVENTION

A semiconductor device manufacturing method according to a first aspect of the present invention comprises the steps of forming a dummy gate electrode on a semiconductor device; with the dummy gate electrode used as a mask, forming a pair of first impurity diffusion layers in those regions of the semiconductor substrate which are opposite to each other through the dummy gate electrode; forming an insulating film on the semiconductor substrate in a way to bury the dummy gate electrode, while exposing an upper surface of the dummy gate; removing the dummy gate electrode and forming a first trench in the insulating film; enlarging the width of the first trench and forming a second trench in the insulating film which is greater in width than the width of the first trench; forming a gate insulating film along an inner surface of the second trench; and forming a gate electrode in the second trench with the gate insulating film intervening therebetween.

Stated in more detail, the method comprises the steps of: forming a first insulating film on a semiconductor substrate; sequentially forming a first semiconductor film and a second insulating film on the first insulating film; forming a resist pattern on the second insulating film; with the resist pattern used as a mask, patterning the first semiconductor film and the second insulating film by an anisotropic etching to provide a stacked layer structure of the first semiconductor layer and the second insulating film; with the stacked layer structure used as a mask, ion-implanting an impurity in the semiconductor substrate to provide first impurity diffusion layer regions for a source and a drain; forming a third insulating film over the semiconductor substrate to bury the stacked layer structure; etching back the third insulating film to expose an upper surface of the stacked layer structure; with the third insulating film used as a mask, removing the stacked layer structure to form a trench in the third insulating film; after forming the trench, enlarging the width of the trench by an isotropic etching; after enlarging the width of the trench, depositing a fourth insulating film along the inner surface of the trench; and forming a conductive layer of a gate electrode on the fourth insulating film.

A semiconductor device according to a second aspect of the present invention comprises a semiconductor device; a first impurity diffusion layer formed in the semiconductor substrate; a second impurity diffusion layer formed in the semiconductor substrate in a spaced-apart relation to the first impurity diffusion layer; a first insulating-layer formed on the first impurity diffusion layer; a second insulating layer formed on the second impurity diffusion layer; a trench formed over the semiconductor substrate in a manner to be defined between the first insulating layer and the second insulating layer; a gate insulating film lined on a bottom surface and an inner sidewall surface of the trench; and a gate electrode formed in the trench with the gate insulating film intervening therebetween, the gate electrode being formed in an overlapped relation to the first and second impurity diffusion regions.

In the semiconductor manufacturing method of the present invention, since there is the step of enlarging the width of the trench, it is possible to suppress the occurrence of an offset between the conductive layer of the gate electrode and the impurity diffusion layer regions.

Since the width of the trench is enlarged by the isotropic etching, it is possible to suppress the occurrence of an offset even in the case where a sidewall insulating film is formed around a stacked gate structure and, by doing so, the so-called LDD (Lightly Doped Drain) structure is obtained.

Further, the isotropic etching treatment using HF or NH₄F is done at the time of enlarging the width of the trench and it is possible to control an offset more precisely.

Further, if the chemical vapor deposition method or sputtering method is used in the formation of a gate insulating film of a high dielectric constant, this insulating film can be deposited on the sidewall of the trench and, by doing so, the gate electrode can be easily formed at a desired area in the trench. It is, therefore, possible to control an offset more precisely.

Even if, in the semiconductor device of the present invention, a gate insulating film of a high dielectric constant is formed on the inner surface of the trench, the gate electrode can be formed in an overlapped relation to the ends of the source/drain regions and the semiconductor device operates stably.

As the high dielectric-constant film use can be made of any of Ta₂O₅, silicon nitride, Al₂O₃ (alumina), BaSrTiO₃, Zr oxide, Hf oxide, Sc oxide, Y oxide and Ti oxide and the resultant semiconductor device operates more stably.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIGS. 1 to 6 are cross-sectional views of a MISFET showing a conventional MISFET manufacturing method stepwise in the formation of a buried type gate electrode structure using a dummy gate electrode;

FIG. 7 is a cross-sectional view showing a conventional MISFET with a thicker gate insulating film formed in a trench;.

FIG. 8 is a cross-sectional view showing a MISFET for explaining a gate offset problem in a MISFET having a high dielectric-constant gate insulating film and buried type gate electrode; and

FIGS. 9 to 16 are cross-sectional views of a MISFET showing, stepwise, a method according to the present invention which manufactures a MISFET having a high-dielectric gate insulating film and buried gate electrode structure.

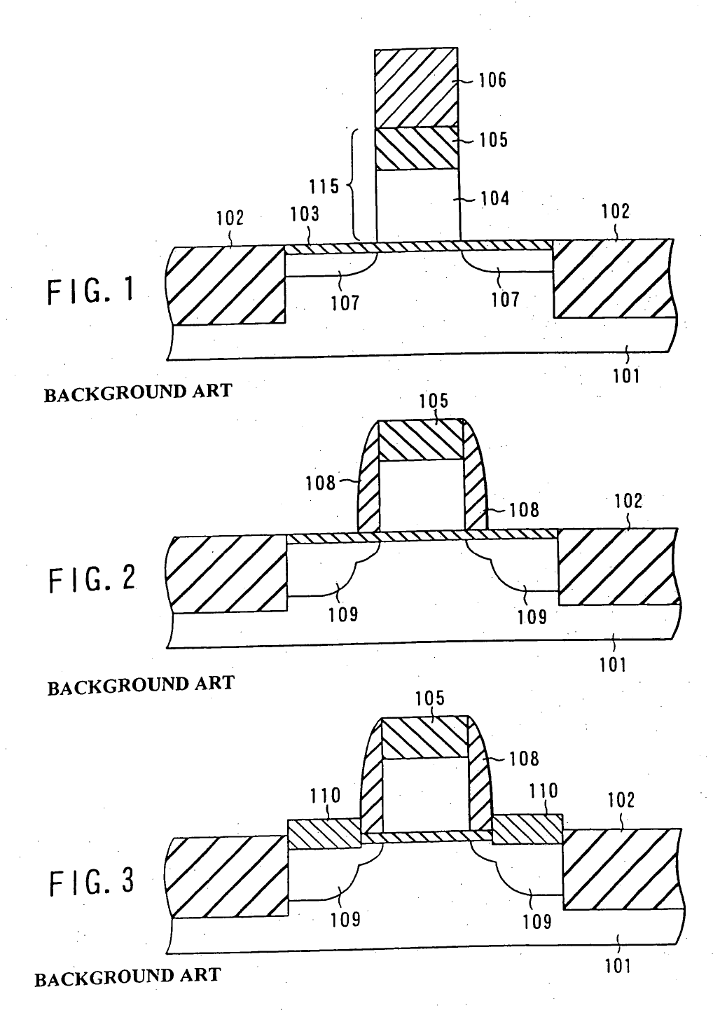

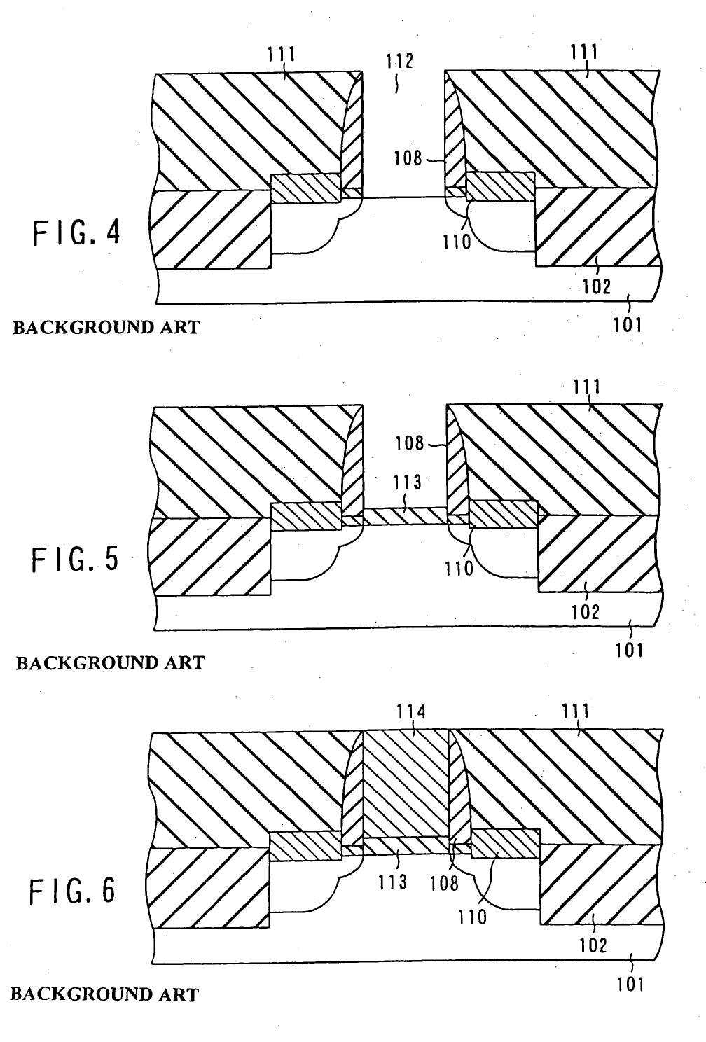

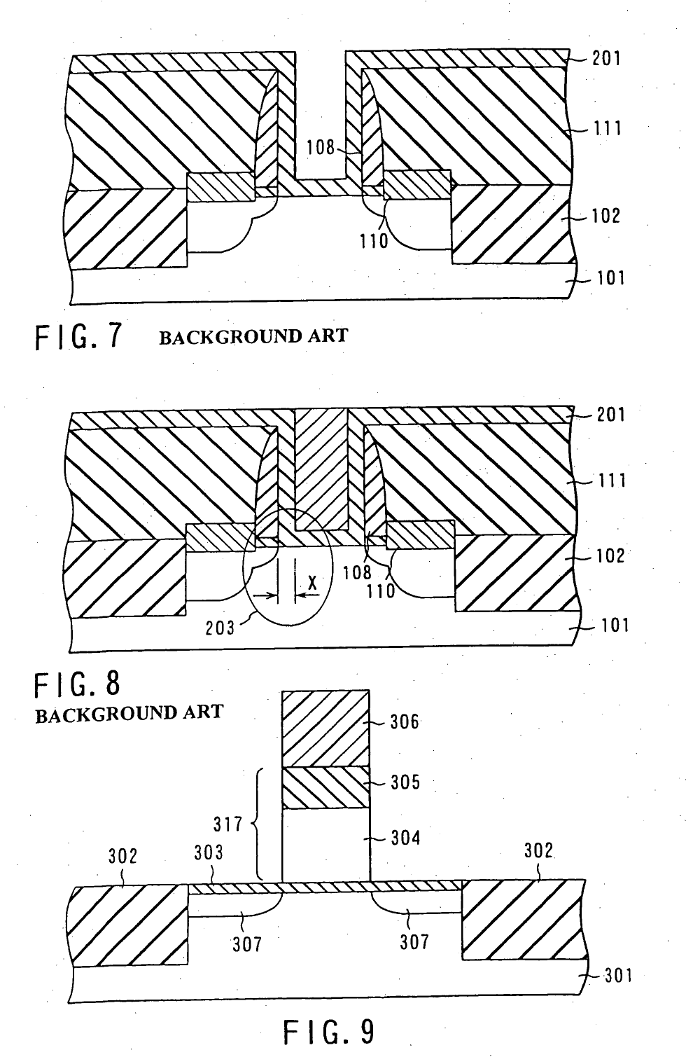

### DETAILED DESCRIPTION OF THE INVENTION

An embodiment of the present invention will be explained below by taking an n type MISFET as an example. FIGS. 9 to 15 are cross-sectional views showing a method for manufacturing a MSIFET of the present invention in a stepwise manner.

After forming an isolation region 302 on a p type semiconductor substrate 301, as shown in FIG. 9, an about 5 nm-thick SiO₂ film 303 serving as a dummy gate insulating film is deposited by a thermal oxidation method on a surface of the substrate 301. Thereafter, an about 100 nm-thick polycrystalline silicon film 304 serving as a dummy gate electrode is deposited by a chemical vapor deposition method, etc., on the SiO₂ film 303. Thereafter, an about 50 nm-thick silicon nitride film 305 is stacked by the chemical vapor deposition method, etc., on the polycrystalline silicon film 304.

Thereafter, using, as a mask, a resist mask 306 formed by a lithography method to a predetermined configuration, a stacked layer structure of the polycrystalline silicon film 304 and silicon nitride film 305 is anistropically etched to a predetermined configuration to provide a dummy gate electrode 317.

The gate length of the dummy gate electrode formed at this time is a finally formed gate length and, for example, about 80 nm. Thereafter, with the dummy gate electrode 317 used as a mask, an n type impurity, such as arsenic, is ion-implanted in a self-aligned way to provide extension regions 307 for later forming source/drain impurity diffusion layers.

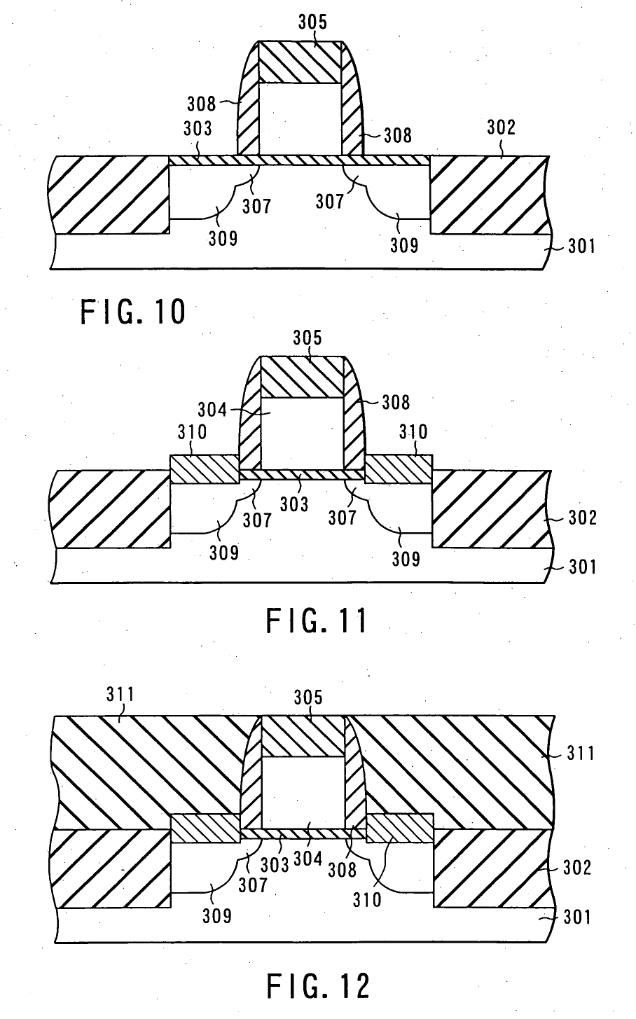

Then, an about 100 nm-thick SiO₂ film is deposited by, for example, the chemical vapor deposition method over a whole surface of the structure shown in FIG. 9. Thereafter, the whole surface of the structure is anisotropically etched to leave the SiO₂ film only on the sidewall area of the dummy gate electrode 317 to provide a sidewall insulating film 308. Thereafter, with the sidewall insulating film 308 and dummy gate electrode 317 as a mask, an n type impurity, such as arsenic and phosphorus, is ion-implanted to provide impurity diffusion layers 309 of n type source/drain having a deep junction (FIG. 10).

An about 20 nm-thick Co film, for example, is deposited on the whole surface of the structure shown in FIG. 10, followed by the application of a heat treatment. By this heat treatment, Co silicide films 310 are selectively formed only on a Co film/Si film contacting areas to provide a silicide structure (FIG. 11).

An about 400 nm-thick insulating film, such as an SiO₂ film, serving as an interlayer insulator 311 is deposited over a whole surface of the structure of FIG. 11 with the use of a chemical vapor deposition method, for example. The whole surface of this structure is polished by using a CMP method to provide an interlayer insulator 311 having a height of the dummy gate electrode 317. If, at this time, use is made of a CMP method utilizing a selectivity between the interlayer insulator 311 and silicon nitride film 305, then the CMP process can be easily finished to a level at which the upper portion of the dummy gate electrode 317 is exposed (FIG. 12).

Thereafter, the silicon nitride film 305 of the dummy electrode 317 is eliminated by an etching having a selectivity between the SiO₂ film (the interlayer insulator 311 and sidewall insulating film 308) and the silicon nitride film 305 by a process using a phosphoric acid solution.

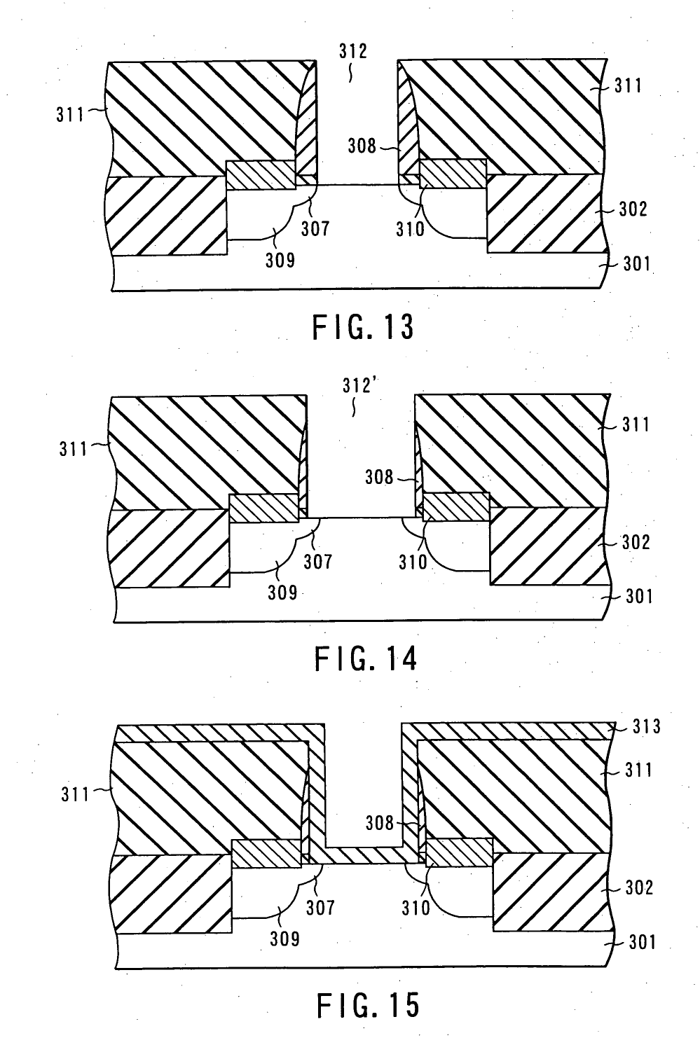

Further, the polycrystalline silicon film 304 of the dummy gate electrode 317 is eliminated by an etching process having a selectivity between the interlayer insulator 311 and the polycrystalline silicon film 304 by a chemical dry etching using a CF₄ series gas. This provides a trench 312 for burying a material for forming a final gate electrode (FIG. 13).

Thereafter, as shown in FIG. 14, the width of the trench 312 is enlarged by an extent corresponding to the film thickness of a desired gate insulating film. In the case of using a Ta₂O₅ film of 40 nm as the gate insulating film, an etching process is done on the sidewall surface of the trench 312 to an extent corresponding to 40 nm or more. By doing so, the trench 312 is enlarged to a trench 312′ for burying a material for a final gate electrode. It is desirable to perform an etching at this time such that both the dummy gate insulating film 303 present on the bottom and sidewall insulating film 308 present on the sidewall area of the burying trench are simultaneously etched, with an adequate selectivity to the semiconductor substrate 101. In the present embodiment using an SiO₂ for both the dummy gate insulating film 303 and sidewall insulating film 308 and a silicon for the semiconductor substrate 101, it is effective to perform an etching using a dilute HF or dilute NH₄F, etc., or an isotropic dry etching using a CDE, etc., that is, an etching having a selectivity to the substrate.

Further, if, in this step, the width of the trench 312′ is further enlarged by an etching to an extent exceeding the thickness of the sidewall insulating film 308, even when a thicker gate insulating film is formed at a later step, it is easy to obtain an overlapped structure in which the end of the gate electrode 314 overlaps the extensions 307 of the impurity diffusion layers 309. By doing so, it is possible to obtain a MISFET of a stabler operation.

Although, in FIG. 14, the trench 312′ is formed to an extent not reaching the silicide layer 310, it may be possible to form the trench 312′ in a manner to expose the silicide layer 310. As set out below, the gate insulating film is lined on the inner surface of the trench so that no short circuiting occurs between the silicide layer 310 and the later-formed gate electrode.

Subsequently, an about 40 nm-thick Ta₂O₅ film is deposited, as a desired gate insulating film material, over the structure shown in FIG. 14 with the use of the chemical vapor deposition method and sputtering method. By doing so, the gate insulating film 313 is deposited on the interlayer insulator 311 and on the exposed inner surface of the trench 312′ including the semiconductor substrate surface (FIG. 15).

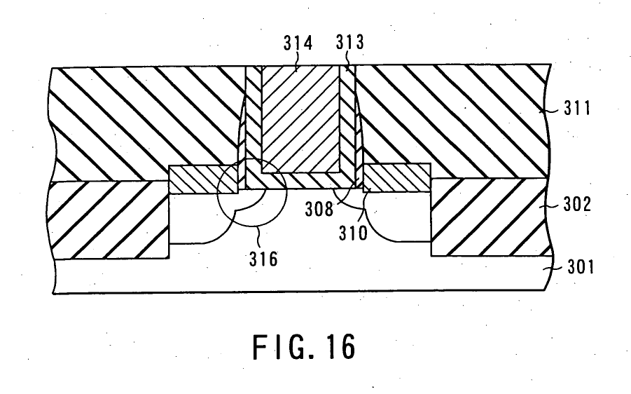

Then, a 300 nm-thick tungsten, etc., serving as a final gate electrode 314 is deposited by the chemical vapor deposition method, sputtering method, etc., over the gate insulating film 313 on the structure shown in FIG. 15. Thereafter, a CMP polishing is done and the burying of tungsten as the gate electrode 314 in the trench 312′ is completed (FIG. 16).

Although, in-the above-mentioned embodiment, the use of the Ta₂O₅ film as the material of the gate insulating film has been explained by way of an example, use can be made of an insulating film, for example, a silicate film such as a silicon nitride film and silicon oxide film, BST (BaSrTiO₃) film, alumina film, Zr oxide film, Hf oxide film, Y oxide film, Sc oxide film and Ti oxide film, so long as it can be properly covered on the inner surface of the trench 312′.

In this case, any optimal method compatible with each material, such as the chemical vapor deposition method and sputtering method is selected as such a formation method.

As set out above, with the microminiaturization of the semiconductor element, the gate insulating film becomes thinner and thinner. For the case of the SiO₂ film (relative dielectric constant: 3.9), the leakage current problem arises through a gate insulating film of below 2 nm. In order to secure the thickness of the gate insulating film to some extent, it is desirable to use a dielectric material having a relative dielectric constant of above 5, such as a silicon nitride film (relative dielectric constant: about 7), Al₂O₃ (alumina) (relative dielectric constant: about 10), Ta₂O₅ film, Zr oxide film, Hf oxide film, etc., (relative dielectric constant: 20 to 25).

Before forming the gate insulating film 313 in the above-mentioned embodiment, an isotropic etching is done on the insulating film 311 constituting the trench 312 to initially enlarge the width of the groove 312 in a substrate direction. Even in the case, therefore, where the gate insulating film 314 has to be formed by the chemical vapor deposition method and sputtering method on the inner surface of the trench 312, it is possible to readily control an offset between the end of the .gate electrode 314 and extensions 307 at the ends of the source/drain diffusion layers 309. Further, the MISFET having a buried type gate electrode formed by such a method operates stably because an offset structure is avoided as indicated by 316 in FIG. 17 in spite of using a high dielectric-constant film as the gate insulating film.

In the manufacture of a MISFET having a buried type gate electrode by the method of the present invention, it is possible to control an offset between the end of the gate electrode and the ends of the source/drain diffusion layers and, due to a specific structure of the present invention, the MISFET operates stably.

Additional advantages and modifications will readily occur to those skilled in the art. Therefore, the invention in its broader aspects is not limited to the specific details and representative embodiments shown and described herein. Accordingly, various modifications may-be made without departing from the spirit or scope of the general inventive concept as defined by the appended claims and their equivalents.

What is claimed is:

1. A method for manufacturing a semiconductor device comprising the steps of:
forming a dummy gate electrode on a semiconductor substrate;
with the dummy gate electrode used as a mask, forming one pair of first impurity diffusion layers in those regions of the semiconductor substrate which are opposite to each other through the dummy gate electrode;
forming an insulating film on the semiconductor substrate in a way to bury the dummy gate electrode, while exposing an upper surface of the dummy gate. electrode;
removing the dummy gate electrode and forming a first trench in the insulating film;
enlarging the width of the first trench and forming a second trench in the insulating film which is greater in width than the width of the first trench;
forming a gate insulating film along an inner surface of the second trench; and
forming a gate electrode in the second trench with the gate insulating film intervening therebetween.

2. The method according to claim 1, further comprising the steps of:
after forming the first impurity diffusion layers, forming a side wall insulating film on a side wall surface of the dummy gate electrode; and
with the dummy gate electrode and the sidewall insulating film used as a mask, forming second impurity diffusion layers having a deeper junction in the semiconductor substrate than the first impurity diffusion layers.

3. The method according to claim 1, wherein the step of forming a second trench includes a step of performing an isotropic etching on the insulating film having the first trench formed therein.

4. The method according to claim 1, wherein the step of forming a gate insulating film includes a step of forming a gate insulating film in a manner to make the width of the second trench equal to, or greater than, that of the first trench.

5. The method according to claim 1, wherein the step of forming the gate insulating film includes a step of using an insulating material having a relative dielectric constant of above 5.

6. The method according to claim 1, wherein the step of forming a gate insulating film includes a step of using one selected from the group consisting of Ta₂O₅, silicon nitride, Al₂O₃, BaSrTiO₃, Zr oxide, Hf oxide, Sc oxide, Y oxide and Ti oxide.

7. A method for manufacturing a semiconductor device, comprising the steps of:
forming a first insulating film on a semiconductor substrate;
sequentially forming a first semiconductor film and a second insulating film on the first insulating film;
forming a resist pattern-on the second insulating film;
with the resist pattern used as a mask, patterning the first semiconductor film and the second insulating film by an anisotropic etching to provide a stacked layer structure of the first semiconductor film and the second insulating film on the semiconductor substrate;
with the stacked layer structure used as a mask, ion-implanting an impurity in the semiconductor substrate to provide first impurity diffusion layers for a source and a drain;
forming a third insulating film over the semiconductor structure to bury the stacked layer structure;
etching back the third insulting film to expose an upper surface of the stacked layer structure;
with the third insulating film used as a mask, removing the stacked layer structure to form a trench in the third insulating film;
after forming the trench, enlarging the width of the trench by an isotropic etching;
after enlarging the width of the trench, depositing a fourth insulting film along an inner surface of the trench; and
forming a conductive layer of a gate electrode on the fourth insulating film.

8. The method according to claim 7, further comprising the steps of:
after providing the first impurity diffusion layers, forming a sidewall insulating film on a sidewall of the stacked layer structure; and
with the sidewall insulating film and the stacked layer structure used as a mask, forming second impurity diffusion layers having a deeper junction in the semiconductor substrate than the first impurity diffusion layers.

9. The method according to claim 7, wherein the step of enlarging the width of the trench includes a step of using, as the isotropic etching, an etching treatment including HF or NH₄F.

10. The method according to claim 7, wherein the step of depositing a fourth insulating film includes a step of depositing a fourth insulating film by a chemical vapor deposition method or a sputtering method.

11. The method according to claim 7, wherein the step of depositing a fourth insulting film comprises a step of forming the fourth insulating film to make the width of the trench after forming the fourth insulating film equal to, or greater than, that of the first trench.

12. The method according to claim 7, wherein the step of depositing a fourth insulting film includes a step of using an insulating material having a dielectric constant of above 5.

13. The method according to claim 7, wherein the step of depositing a fourth insulating film includes a step of using one selected from the group consisting of Ta₂O₅, silicon nitride, Al₂O₃, BaSrTiO₃, Zr oxides Hf oxide, Sc oxide, Y oxide and Ti oxide.

14. A semiconductor device comprising:
a semiconductor substrate;
a first impurity diffusion layer formed in the semiconductor substrate;
a second impurity diffusion layer formed in the semiconductor substrate in a spaced-apart relation to the first impurity diffusion layer;
a first insulating layer formed on the first impurity diffusion layer;
a second insulating layer formed on the second impurity diffusion layer;
a trench formed over the semiconductor substrate in a manner to be defined between the first insulting layer and the second insulating layer;
a gate insulating film lined on a bottom surface and an inner sidewall surface of the trench; and
a gate electrode formed in the trench with the gate insulting film intervening therebetween, the gate electrode being formed in an overlapped relation relative to the first impurity diffusion layer and the second impurity diffusion layer.

15. The semiconductor device according to claim 14, wherein the gate insulting film is formed of an insulting material having a dielectric constant of above 5.

16. The semiconductor device according to claim 14, wherein the gate insulating film contains one selected from the group consisting of Ta₂O₅, silicon nitride, Al₂O₃, BaSrTiO₃, Zr oxide, Hf oxide, Sc oxide, Y oxide, and Ti oxide.

17. The semiconductor device according to claim 14, wherein the first impurity diffusion layer and the second impurity diffusion layer, each, comprise a third impurity diffusion layer including a portion formed beneath the gate insulating film formed on the inner sidewall surface of the trench and a fourth impurity diffusion layer including a portion formed beneath any of the first insulating layer and second insulating layer and having a deeper junction in the semiconductor substrate than the third impurity diffusion layer.

18. The semiconductor device according to claim 14, further comprising a metal silicide layer formed on the first impurity diffusion layer and the second impurity diffusion layer at those areas beneath the first insulating layer and the second insulating layer.
